(19) United States
(12) Patent Application Publication
(10) Pub. No.: US 2013/0166238 A1
(43) Pub. Date: Jun. 27, 2013

(54) CIRCUIT FOR MEASURING CAPACITANCE AND PARASITIC RESISTANCE OF A CAPACITOR

(71) Applicants: YUN BAI, Shenzhen City (CN); SONG-LIN TONG, Shenzhen City (CN)

(72) Inventors: YUN BAI, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/435,075

(22) Filed: Mar. 30, 2012

(30) Foreign Application Priority Data
Dec. 23, 2011 (CN) 201110437279.6

(51) Int. Cl. G01R 27/02

(52) U.S. Cl. 702/65

(57) ABSTRACT

A measuring circuit includes a voltage converting circuit, a discharging and sampling circuit, a control circuit, and a charging circuit. The voltage converting circuit converts a voltage to a working voltage and outputs the working voltage to the discharging and sampling circuit. The charging circuit charges a capacitor and outputs a stop charging signal to the control circuit. The control circuit includes a microprocessor with a timer, to output a discharging control signal to the discharging and sampling circuit for controlling the capacitor to discharge according to the stop charging signal. The discharging and sampling circuit includes a discharging resistor, and measures voltages of the capacitor and the discharging resistor. The microprocessor obtains a discharging time of the capacitor for calculating a capacitance of the capacitor, and obtains the voltages of the capacitor and the discharging resistor for calculating a parasitic resistance of the capacitor.

### BACKGROUND

1. Technical Field

The present disclosure relates to circuits, and particularly to a circuit for measuring capacitance and parasitic resistance of a capacitor.

2. Description of Related Art

Capacitors are used for storing electrical charges and as filters. Electronic devices, such as mobile phones and notebook computers, require high quality and accurate capacitance value of capacitors. Thus capacitors need to be accurately measured before being used in these electronic devices. The present measurement apparatus uses a capacitance-bridge method to measure capacitance and parasitic resistance of the capacitors. However, the capacitance-bridge method is adapted to measure capacitors having small capacitances. When the capacitance of the capacitors is high, the measuring precision is not high enough. Therefore, there is room for improvement in the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a block diagram of a circuit for measuring capacitance and parasitic resistance of a capacitor, in accordance with an exemplary embodiment.

FIGS. 2 to 5 are circuit diagrams of the circuit of FIG. 1, in accordance with exemplary embodiments.

### DETAILED DESCRIPTION

The disclosure, including the drawings, is illustrated by way of example and not by way of limitation. References to “an” or “one” embodiment in this disclosure are not necessarily to the same embodiment, and such references mean at least one.

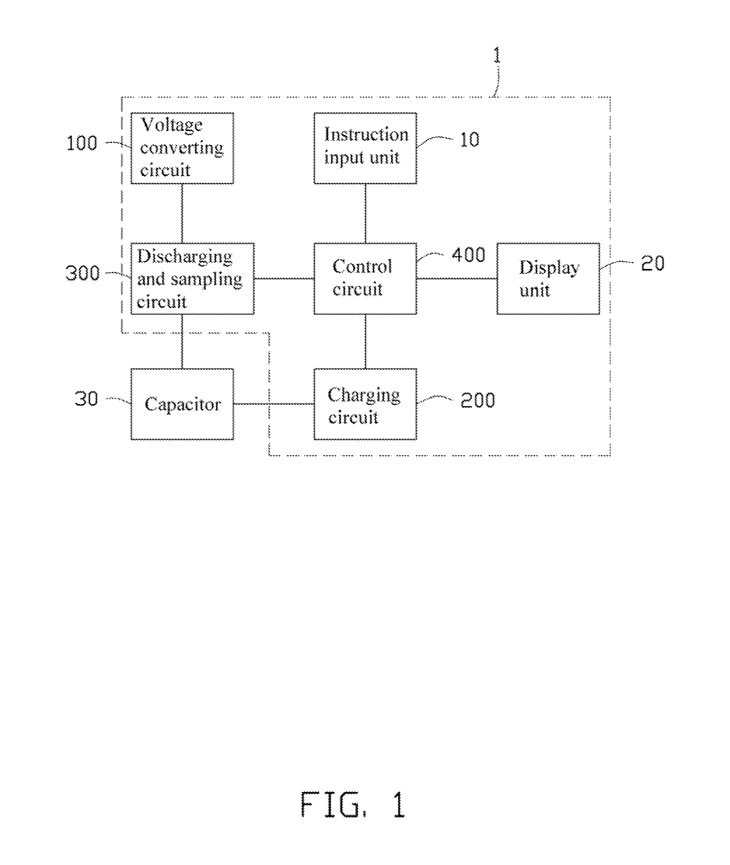

Referring to FIG. 1, an embodiment of a circuit 1 for measuring capacitance and parasitic resistance of a capacitor 30 includes an instruction input unit 10, a display unit 20, a voltage converting circuit 100, a charging circuit 200, a discharging and sampling circuit 300, and a control circuit 400. The discharging and sampling circuit 300 is connected to the voltage converting circuit 100 and the capacitor 30. The charging circuit 200 is connected to the capacitor 30. The control circuit 400 is connected to the instruction input unit 10, the display unit 20, the charging circuit 200, and the discharging and sampling circuit 300.

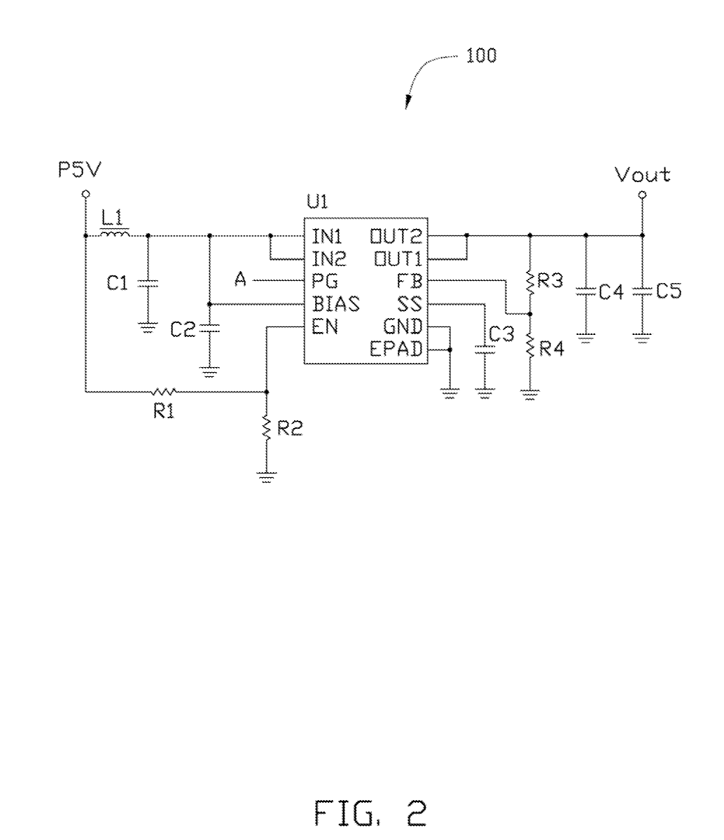

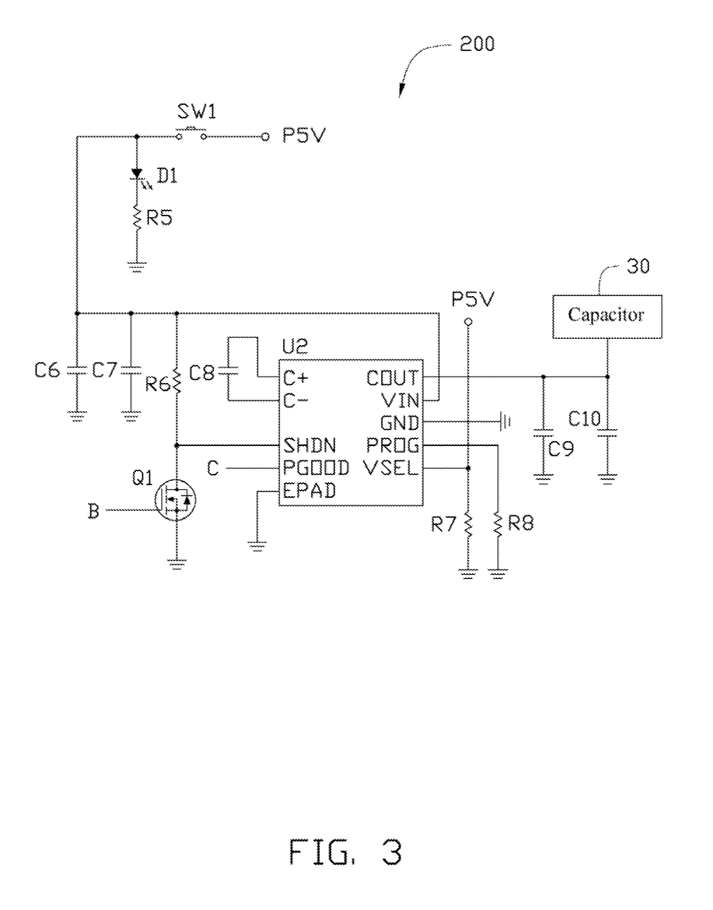

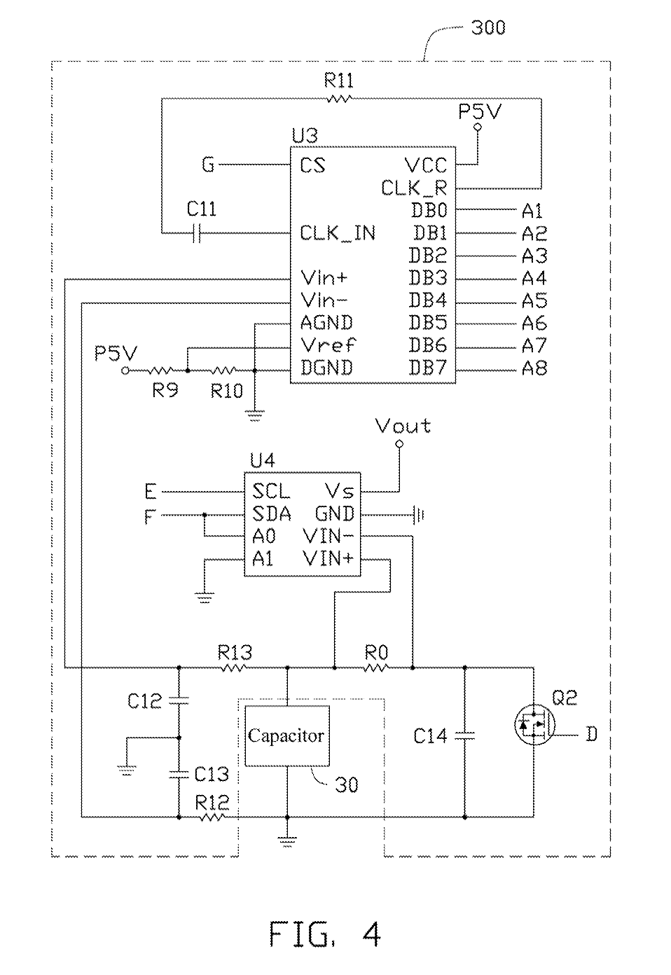

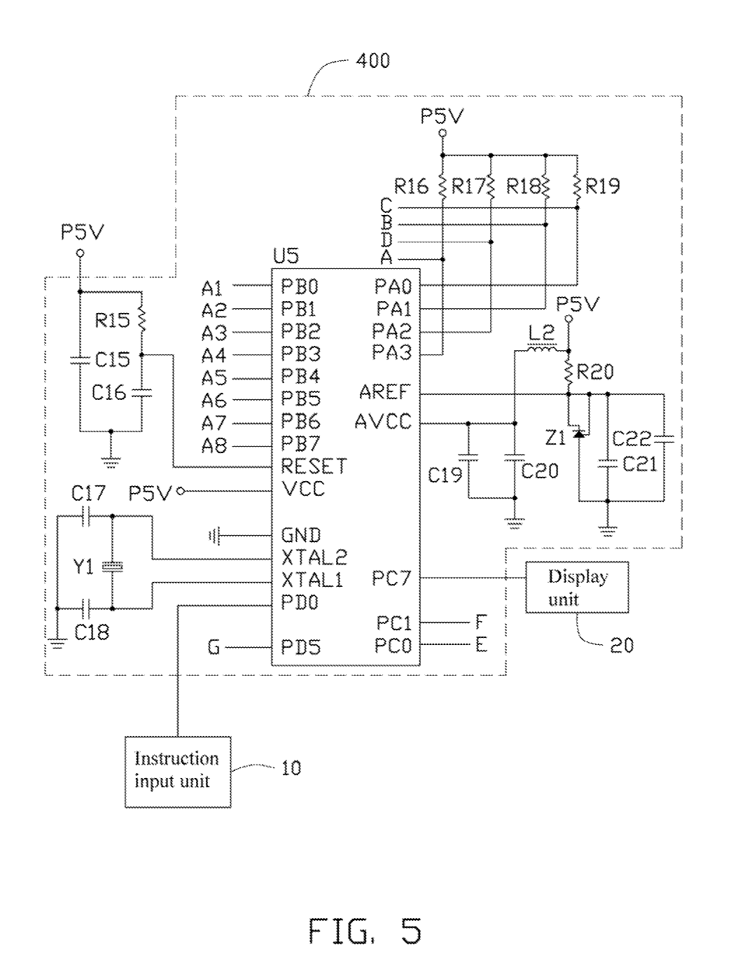

Referring to FIGS. 2-5, the voltage converting circuit 100 receives a voltage from a power source P5V, converts the voltage to a working voltage, and provides the working voltage to the discharging and sampling circuit 300. The charging circuit 200 charges the capacitor 30. The discharging and sampling circuit 300 includes a discharging resistor RO, the discharging and sampling circuit 300 controls the capacitor 30 to discharge and measure voltages of the capacitor 30 and the discharging resistor R0. The control circuit 400 includes a microprocessor U5 with a timer. The microprocessor U5 receives a stop charging signal from the charging circuit 200, controls the charging circuit 200 to stop charging the capacitor 30, and outputs a discharging control signal to the discharging and sampling circuit 300 for controlling the capacitor 30 to discharge. The microprocessor U5 obtains a discharging time of the capacitor 30, and calculates a capacitance of the capacitor 30 according to the discharging time of the capacitor 30 and the resistance of the discharging resistor RO. The microprocessor U5 also controls the discharging and sampling circuit 300 to measure a saturation voltage of the capacitor 30 when the capacitor 30 is charged fully, and measures a discharging voltage of the capacitor 30 and a voltage of the discharging resistor RO at any time during discharging of the capacitor 30, thereby calculating the parasitic resistance of the capacitor 30. In one embodiment, the instruction input unit 10 is a keyboard having a plurality of keys, to input instructions. The display unit 20 is a liquid crystal display screen. The capacitor 30 is a super capacitor.

The voltage converting circuit 100 includes capacitors C1-C5, resistors R1-R4, a power converting chip U1, an inductor L1, and a voltage output terminal Vout. Two input pins IN1 and IN2 of the power converting chip U1 are both connected to the power source P5V through the inductor L1. The resistors R1 and R2 are connected between the power source P5V and ground in series. An input/output (I/O) pin EN of the power converting chip U1 is connected to a node between the resistors R1 and R2. The capacitor C1 is connected between the input pin Ni of the power converting chip U1 and ground. An I/O pin PG of the power converting chip U1 is connected to the control circuit 400. An I/O pin BIAS of the power converting chip U1 is connected to the input pin IN1 of the power converting chip U1 and also grounded through the capacitor C2. Two output pins OUT1 and OUT2 of the power converting chip U1 are both connected to the voltage output terminal Vout. The capacitors C4 and C5 are connected between the voltage output terminal Vout and ground in parallel. The resistors R3 and R4 are connected between the output pin OUT2 of the power converting chip U1 and ground, in series. An I/O pin FB of the power converting chip U1 is connected to a node between the resistors R3 and R4. An I/O pin SS of the power converting chip U1 is grounded through the capacitor C3. Ground pins GND and EPAD of the power converting chip U1 are grounded.

The charging circuit 200 includes a field effect transistor (FET) Q1, a switch SW1, capacitors C6-C10, resistors R5-R8, a light emitting diode (LED) D1, and a charging chip U2. An input pin VIN of the charging chip U2 is connected to the power source P5V through the switch SW1. An anode of the LED D1 is connected to the input pin VIN of the charging chip U2. A cathode of the LED D1 is grounded through the resistor R5. The capacitors C6 and C7 are connected between the input pin VIN of the charging chip U2 and ground, in parallel. A drain of the FET Q1 is connected to an I/O pin SHDN of the charging chip U2, and also connected to the input pin VIN of the charging chip U2 through the resistor R6. A source of the FET Q1 is grounded. A gate of the FET Q1 is connected to the control circuit 400. The capacitor C8 is connected between I/O pins C+ and C− of the charging chip U2. An I/O pin PGOOD of the charging chip U2 is connected to the control circuit 400. Ground pins EPAD and GND of the charging chip U2 are grounded. An output pin COUT of the charging chip U2 is connected to the capacitor 30. The capacitors C9 and C10 are connected between the output pin COUT of the charging chip U2 and ground, in parallel. An I/O pin PROG of the charging chip U2 is grounded through the resistor R8. An I/O pin VSEL of the charging chip U2 is connected to the power source P5V, and also grounded through the resistor R7.

The discharging and sampling circuit 300 includes the discharging resistor R0, a FET Q2, an analog to digital (A/D) converting chip U3, a sampling chip U4, capacitors C11-C14, and resistors R9-R13. The capacitor C11 and the resistor R11 are connected between I/O pins CLK IN and CLK R of the A/D converting chip U3. An I/O pin CS of the A/D converting chip U3 is connected to the control circuit 400. An input pin Vin+ of the A/D converting chip U3 is connected to a first end of the capacitor 30 through the resistor R13. An input pin Vin− of the A/D converting chip U3 is connected to a second end of the capacitor 30 through the resistor R12. Ground pins AGND and DGND of the A/D converting chip U3 are connected to ground, and are also connected to the power source P5V through the resistors R10 and R9 connected in series. An I/O pin Vref of the A/D converting chip U3 is connected to a node between the resistors R9 and R10. A voltage pin Vcc of the A/D converting chip U3 is connected to the power source P5V. I/O pins DB0-DB7 of the A/D converting chip U3 are connected to the control circuit 400. The capacitor C12 is connected between the input pin Vin+ of the A/D converting chip U3 and ground. The capacitor C13 is connected between the input pin Vin− of the A/D converting chip U3 and ground. A drain of the FET Q2 is connected to the first end of the capacitor 30 through the discharging resistor RO. A source of the FET Q2 is connected to the second end of the capacitor 30, and is also grounded. A gate of the FET Q2 is connected to the control circuit 400. The capacitor C14 is connected between the drain of the FET Q2 and the source of the FET Q2. One end of the discharging resistor RO is connected to input pin VIN+ of the sampling chip U4, the other end of the discharging resistor RO is connected to VIN− of the sampling chip U4. A voltage pin Vs of the sampling chip U4 is connected to the voltage output terminal Vout of the voltage converting circuit 100. I/O pins SCL and SDA of the sampling chip U4 are connected to the control circuit 400. An I/O pin AO of the sampling chip U4 is connected to the I/O pin SDA of the sampling chip U4. Ground pins GND and Al of the sampling chip U4 are grounded.

The control circuit 400 includes the microprocessor U5, capacitors C15-C22, resistors R15-R20, a crystal oscillator Y1, a regulating diode Z1, and an inductor L2. In one embodiment, the microprocessor U5 is a single chip. I/O pins PB0-PB7 of the microprocessor U5 are connected to corresponding I/O pins DB0-DB7 of the A/D converting chip U3 of the discharging and sampling circuit 300. I/O pins PA0-PA3 of the microprocessor U5 are connected to the power source P5V through the resistors R19, R18, R17, and R16 respectively. A voltage pin VCC of the microprocessor U5 is connected to the power source P5V. A ground pin GND of the microprocessor U5 is grounded. An I/O Pin PD0 of the microprocessor U5 is connected to the instruction input unit 10. An I/O pin PD5 of the microprocessor U5 is connected to the I/O pin CS of the A/D converting chip U3 of the discharging and sampling circuit 300. An I/O pin PC7 of the microprocessor U5 is connected to the display unit 20. I/O pins PC1 and PC0 of the microprocessor U5 are respectively connected to the I/O pins SDA and SCL of the sampling chip U4. A reset pin RESET of the microprocessor U5 is connected to the power source P5V through the resistor R15, and is also grounded through the capacitor C16. The capacitor C15 is connected between the power source P5V and ground. A clock pin XTAL2 of the microprocessor U5 is grounded through the capacitor C17. A clock pin XTAL1 of the microprocessor U5 is grounded through the capacitor C18. The crystal oscillator Y1 is connected between the clock pins XTAL2 and XTAL1 of the microprocessor U5. A reference voltage pin AREF of the microprocessor U5 is connected to a control terminal of the regulating diode Z1. A cathode of the regulating diode Z1 is connected to the power source P5V through the resistor R20, and also connected to the control terminal of the regulating diode Z1. An anode of the regulating diode Z1 is grounded. The capacitors C21 and C22 are connected between the control terminal of the regulating diode Z1 and ground, in parallel. An analog voltage pin AVCC of the microprocessor U5 is connected to the power source P5V through the inductor L2. The capacitors C19 and C20 are connected between the analog voltage pin AVCC of the microprocessor U5 and ground, in parallel. The I/O pin PA3 of the microprocessor U5 is connected to the I/O pin PG of the power converting chip U1 of the voltage converting circuit 100. The I/O pin PA2 of the microprocessor U5 is connected to the gate of the FET Q2. The I/O pin PA1 of the microprocessor U5 is connected to the gate of the FET Q1 of the charging circuit 200. The I/O pin PA0 of the microprocessor U5 is connected to the I/O pin PGOOD of the charging chip U2 of the charging circuit 200.

In use, the voltage converting circuit 100 receives a 5 volt (5V) from the power source P5V, converts the 5V to 3.3V, and outputs the 3.3V to the discharging and sampling circuit 300 through the voltage output terminal Vout. The I/O pin PA1 of the microprocessor U5 outputs a low level signal to the FET Q1. The FET Q1 is turned off. After the switch SW1 is turned on, the 5V is provided to the charging chip U2 for charging the capacitor 30. The LED D1 is lit, indicating that the 5V is normal. When the capacitor 30 is fully charged, the I/O pin PGOOD of the charging chip U2 outputs a control signal to the I/O pin PA0 of the microprocessor U5, to control the I/O pin PA1 of the microprocessor U5 to output a high level signal to the FET Q1. The FET Q1 is turned on. The 5V is provided to the resistor R6 and the FET Q1, to prevent the 5V from charging the capacitor 30 through the charging chip U2. The input pins Vin+ and Vin− of the A/D converting chip U3 measure a saturation voltage, such as 5V, of the capacitor 30. The A/D converting chip U3 converts the saturation voltage to a digital signal, and outputs the digital signal to the microprocessor U5 through the input pins DB0-DB7 and PB0-PB7. The microprocessor U5 governs the display unit 20.

The I/O pin PA2 of the microprocessor U5 outputs a high level signal to the FET Q2. The FET Q2 is turned on. The capacitor 30 discharges through the discharging resistor RO and the FET Q2. The timer of the microprocessor U5 counts elapsed time. When the voltage of the capacitor 30 is 0V as measured by the A/D converting chip U3, the timer of the microprocessor U5 stops timing and controls the display unit 20 to display a discharging time of the capacitor 30. This is calculated according to the following format: τ=R×C, wherein τ is a discharging time, R is a resistance of the discharging resistor R0, and C is a capacitance of the capacitor 30. Thus, the capacitance C of the capacitor 30 can be obtained, which is C=τ/R.

For example, when the saturation voltage of the capacitor 30 is 5V, the microprocessor U5 controls the capacitor 30 to discharge, and the timer of the microprocessor U5 starts to time. When the voltage of the capacitor 30 is 0V, the timer of the microprocessor U5 stops timing and obtains a discharging time τ, such as τ=1.83 seconds (S) for example. If the discharging time τ of the capacitor 30 is 1.83 S, and the resistance R of the discharging resistor R0 is 2.2 ohms, thus, the capacitance C=τ/R=1.83/2.2=0.83 farad (F). In this example, the capacitance of the capacitor 30 is 0.83 F.

When a parasitic resistance of the capacitor 30 needs to be measured, the microprocessor U5 receives a sampling signal from the instruction input unit 10 during discharging of the capacitor 30. The microprocessor U5 obtains a discharging voltage VCAP1 of the capacitor 30 at any time through the A/D converting chip U3 and obtains a voltage drop VDrop of the discharging resistor R0 through the sampling chip U4. This is done according to the format: ESR=VDrop/I30, wherein VDrop is a difference between the saturation voltage VCAP and the discharging voltage VCAP1, I30 is a current value of the capacitor 30, and ESR is the parasitic resistance of the capacitor 30. Since the capacitor 30 is connected to the discharging resistor R0 in series, the current value IR0 of the discharging resistor R0 is the same as the current value I30 of the capacitor 30, according to the format IR0=ΔVR0/R, wherein the ΔVR0 is the voltage drop of the discharging resistor R0, and R is the resistance of the discharging resistor R0.

For example, if the voltage drop ΔVR0=4.28V, and R=2.2 ohm, the current value IR0=4.28/2.2=1.95 ampere (A). That is, the current value I30=IR0=1.95 A. The saturation voltage VCAP=5V and VCAP1=3.6V. Thus, VDrop=VCAP−VCAP1=1.4V, and ESR=Drop/I30=1.4/1.95=0.72 ohm. In this case, the parasitic resistance of the capacitor 30 is 0.72 ohm.

The measuring circuit 1 controls the charging circuit 200 to charge the capacitor 30 through the control circuit 400, and also controls the capacitor 30 to discharge through the discharging and sampling circuit 300, to obtain the saturation voltage and the discharging voltage of the capacitor 30 and the voltage of the discharging resistor R0 through the discharging and sampling circuit 300, for calculating the capacitance and the parasitic resistance of the capacitor 30.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A circuit for measuring capacitance and parasitic resistance of a capacitor, the circuit comprising:
a voltage converting circuit to receive a voltage from a power source and convert the voltage to a working voltage;
a charging circuit to charge the capacitor and output a stop charging signal;
a discharging and sampling circuit comprising a discharging resistor, wherein the discharging and sampling circuit receives the working voltage from the voltage converting circuit, controls the capacitor to discharge, and measure voltages of the capacitor and the discharging resistor; and
a control circuit comprising a microprocessor with a timer, wherein the microprocessor receives the stop charging signal from the charging circuit and outputs a discharging control signal to the discharging and sampling circuit for controlling the capacitor to discharge, the microprocessor obtains a discharging time of the capacitor through the timer, to calculate a capacitance of the capacitor according to the discharging time of the capacitor and a resistance of the discharging resistor, the microprocessor also obtains the saturation voltage of the capacitor, the discharging voltage of the capacitor, and the voltage of the discharging resistor at any time, to calculate a parasitic resistance of the capacitor according to the voltages of the capacitor and the resistance of the discharging resistor.

2. The circuit of claim 1, further comprising an instruction input unit connected to the microprocessor, wherein the microprocessor receives an instruction signal from the instruction input unit and controls the discharging and sampling circuit to obtain the discharging voltage of the capacitor and the voltage of the discharging resistor at any time, to calculate the parasitic resistance of the capacitor according to the voltages of the capacitor and the resistance of the discharging resistor.

3. The circuit of claim 2, further comprising a display unit connected to the microprocessor, to display the voltage and the discharging time of the capacitor.

4. The circuit of claim 3, wherein the voltage converting circuit comprises first to fifth capacitors, first to fourth resistors, a power converting chip, a first inductor, and a voltage output terminal, first and second input pins of the power converting chip are connected to the power source through the first inductor, the first and second resistors are connected between the power source and ground in series, a first input/output (I/O) pin of the power converting chip is connected to a node between the first and second resistors, the first capacitor is connected between the first input pin of the power converting chip and ground, a second I/O pin of the power converting chip is connected to the control circuit, a third I/O pin of the power converting chip is connected to the first input pin of the power converting chip and also grounded through the second capacitor, first and second output pins of the power converting chip are connected to the voltage output terminal, the fourth and fifth capacitors are connected between the voltage output terminal and ground in parallel, the third and fourth resistors are connected between the second output pin of the power converting chip and ground in series, a fourth I/O pin of the power converting chip is connected to a node between the third and fourth resistors, a fifth I/O pin of the power converting chip is grounded through the third capacitor.

5. The circuit of claim 4, wherein the charging circuit comprises a first field effect transistor (FET), a switch, sixth to tenth capacitors, fifth to eighth resistors, a light emitting diode (LED), and a charging chip, an input pin of the charging chip is connected to the power source through the switch, an anode of the LED is connected to the input pin of the charging chip, a cathode of the LED is grounded through the fifth resistor, the sixth and seventh capacitors are connected between the input pin of the charging chip and ground in parallel, a drain of the first FET is connected to a first I/O pin of the charging chip, and also connected to the input pin of the charging chip through the sixth resistor, a source of the first FET is grounded, a gate of the first FET is connected to the control circuit, the eighth capacitor is connected between second and third I/O pins of the charging chip, a fourth I/O pin of the charging chip is connected to the control circuit, the output pin of the charging chip is connected to the capacitor, the ninth and tenth capacitors are connected between the output pin of the charging chip and ground in parallel, a fifth I/O pin of the charging chip is grounded through the eighth resistor, a sixth I/O pin of the charging chip is connected to the power source, and also grounded through the seventh resistor.

6. The circuit of claim 5, wherein the discharging and sampling circuit further comprises a second FET, an analog to digital (A/D) converting chip, a sampling chip, eleventh to fourteenth capacitors, and ninth to thirteenth resistors, the eleventh capacitor and the eleventh resistor are connected between first and second I/O pins of the A/D converting chip in series, a third I/O pin of the A/D converting chip is connected to the control circuit, a first input pin of the A/D converting chip is connected to a first end of the capacitor through the thirteen resistor, a second input pin of the A/D converting chip is connected to a second end of the capacitor through the twelfth resistor, two ground pins of the A/D converting chip are connected to the power source through the tenth and ninth resistors in series, and also grounded, a fourth I/O pin of the A/D converting chip is connected to a node between the ninth and tenth resistors, a voltage pin of the A/D converting chip is connected to the power source, fifth to twelfth I/O pins of the A/D converting chip are connected to the control circuit, the twelfth capacitor is connected between the first input pin of the A/D converting chip and ground, the thirteen capacitor is connected between the second input pin of the A/D converting chip and ground, a drain of the second FET is connected to the first end of the capacitor through the discharging resistor, a source of the second FET is connected to the second end of the capacitor, and also grounded, a gate of the second FET is connected to the control circuit, the fourteen capacitor is connected between the drain of the second FET and the source of the second FET, first and second input pins of the sampling chip are connected to two ends of the discharging resistor, a voltage pin of the sampling chip is connected to the voltage output terminal of the voltage converting circuit, first and second I/O pins of the sampling chip are connected to the control circuit, a third I/O pin of the sampling chip is connected to the second I/O pin of the sampling chip.

7. The circuit of claim 6, wherein the control circuit further comprises fifteenth to twenty-second capacitors, fifteenth to twentieth resistors, a crystal oscillator, a regulating diode, and a second inductor, first to seventh I/O pins of the microprocessor are respectively connected to the fifth to twelfth I/O pins of the A/D converting chip of the discharging and sampling circuit, eighth to eleventh I/O pins of the microprocessor are connected to the power source respectively through the sixteenth to nineteenth resistors, a voltage pin of the microprocessor is connected to the power source, a twelfth I/O pin of the microprocessor is connected to the instruction input unit, a thirteenth I/O pin of the microprocessor is connected to the third I/O pin of the A/D converting chip, a fourteenth I/O pin of the microprocessor is connected to the display unit, fifteenth and sixteenth pins of the microprocessor are respectively connected to the second and first I/O pins of the sampling chip, a reset pin of the microprocessor is connected to the power source through the fifteenth resistor, and also grounded through the sixteenth capacitor, the fifteenth capacitor is connected between the power source and ground, a first clock pin of the microprocessor is grounded through the seventeenth capacitor, a second clock pin of the microprocessor is grounded through the eighteenth capacitor, the crystal oscillator is connected between the first and second clock pins of the microprocessor, a reference voltage pin of the microprocessor is connected to a control terminal of the regulating diode, a cathode of the regulating diode is connected to the power source through the twentieth resistor, and also connected to the control terminal of the regulating diode, an anode of the regulating diode is grounded, the twenty-first and twenty-second capacitors are connected between the control terminal of the regulating diode and ground in parallel, an analogy voltage pin of the microprocessor is connected to the power source through the second inductor, the nineteenth and twentieth capacitors are connected between the analog voltage pin of the microprocessor and ground in parallel, the eleventh I/O pin of the microprocessor is connected to the second I/O pin of the power converting chip of the voltage converting circuit, the tenth I/O pin of the microprocessor is connected to the gate of the second FET, the ninth I/O pin of the microprocessor is connected to the gate of the first FET, the eighth I/O pin of the microprocessor is connected to the fourth I/O pin of the charging chip.

8. The circuit of claim 1, wherein the microprocessor is a single chip.
